(19) United States
(12) Patent Application Publication
(10) Pub. No.: US 2005/0208700 A1
(43) Pub. Date: Sep. 22, 2005

(54) Die to substrate attach using printed adhesive

(75) Inventors: Hyeog Chan Kwon, Seoul (KR); Sang Ho Lee, Yeoju (KR); Jong Wook Ju, Kyoungnam (KR)

Correspondence Address: HAYNES BEFFEL & WOLFELD LLP, P O BOX 366, HALF MOON BAY, CA, 94019, US

(73) Assignee: ChipPAC, Inc., Fremont, CA (US)

(21) Appl. No.: 10/966,572

(22) Filed: Oct. 15, 2004

Related U.S. Application Data
(60) Provisional application No. 60/555,058, filed on Mar. 19, 2004.

(51) Int. Cl. H01L 21/48; H01L 21/50

(52) U.S. Cl. 438/106

(57) ABSTRACT

A semiconductor chip packaging method (34) includes printing an adhesive (46) on a support surface (42), typically a surface of a semiconductor substrate (44), to create individual adhesive areas (40). Semiconductor chips (24) are individually placed on the individual adhesive areas thereby securing the semiconductor chips to the support surface to create first chip subassemblies (55). The semiconductor chip and the semiconductor substrate are electrically connected to create second chip subassemblies (62). At least a portion of each of at least some of the second chip subassemblies is encapsulated to create semiconductor chip packages (64). The adhesive at the individual adhesive areas is preferably a B-staged adhesive so that solvent is removed from the adhesive before the individually placing step.

### CROSS-REFERENCE TO RELATED APPLICATIONS

This application claims priority from U.S. Provisional Application No. 60/555,058, filed Mar. 19, 2004, titled “Die to substrate attach using printed adhesive”.

### BACKGROUND

The present invention relates to the fabrication of semiconductor packages, including single-chip and multi-chip modules.

Semiconductor chip packaging process typically begins with wafer dicing, that is sawing a semiconductor wafer to separate the wafer into individual semiconductor devices or chips. Before sawing, a wafer mounting tape is typically attached to the backside of the wafer. The wafer mounting tape keeps the chips together after sawing.

The semiconductor chip is typically adhered to a previously mounted chip or to the substrate with a paste (typically an epoxy paste adhesive) or a film adhesive. Generally, paste adhesives have been used more often than film adhesives. However, some multi-chip modules are more successfully fabricated using film adhesives because the thickness of adhesive film is uniform so that there is minimal or no tilt of the semiconductor chips and no fillet of adhesive encircling the semiconductor chip. Moreover, no resin is bled so that it is suitable for multi chip stacking and packages with tight design tolerances or thinner chip.

In one method of fabricating a multi-chip module using film adhesive, an adhesive film is laminated directly to the backside of the semiconductor wafer and then the wafer is diced into individual semiconductor chips using conventional wafer dicing equipment. For stacking the semiconductor chips, each chip is lifted by a chip-bonding tool, which is usually mounted at the end of a pick-and-place device, and mounted onto the substrate or onto a semiconductor chip mounted previously. This method requires special film laminating equipment. However, it can shorten fabrication time and lower cost because the paste-dispensing process is not needed.

After the chip mounting process, bonding pads of the chips are connected to bonding pads of the substrate with Au or Al wires during a wire bonding process to create an array of semiconductor chip devices. Finally, the semiconductor chips and their associated wires connected to the substrate are encapsulated, typically using an epoxy-molding compound, to create an array of encapsulated semiconductor devices. The molding compound protects the semiconductor devices from the external environment, such as physical shock and humidity. After encapsulation, the encapsulated devices are separated, typically using a laser saw, into individual semiconductor chip packages.

See U.S. Pat. Nos. 5,776,799; 6,436,732 and 6,503,821.

### SUMMARY

A first aspect of the present invention is directed to a first semiconductor chip packaging method. Adhesive is printed on a support surface to create individual adhesive areas. The support surface may be a surface of a semiconductor substrate or a circuit-containing die or a spacer die. Semiconductor chips are individually placed on the individual adhesive areas thereby securing the semiconductor chips to the support surface to create first chip subassemblies. The first chip subassemblies comprise semiconductor substrates. The semiconductor chip and the semiconductor substrate of each of a plurality of the first chip subassemblies are electrically connected to create second chip subassemblies. At least a portion of each of at least some of the second chip subassemblies is encapsulated to create semiconductor chip packages. The adhesive at the individual adhesive areas may be B-staged, thereby removing solvent from the adhesive, before the individually placing step. The support surface may be a surface of the substrate or may be a surface of a circuit-containing die or a spacer die.

A second aspect of the invention is directed to a second semiconductor chip packaging method. Adhesive is printed on a semiconductor substrate to create individual adhesive areas. The adhesive at the individual adhesive areas is B-staged, thereby removing solvent from the adhesive, before the individually placing step. Semiconductor chips are individually placed on the B-staged individual adhesive areas thereby securing the semiconductor chips to the support surface to create first chip subassemblies. The semiconductor chip and support surface of each of a plurality of the first chip subassemblies are electrically connected to create second chip subassemblies. The electrically connecting step is carried out using wires between wire bond positions on the semiconductor chip and the semiconductor substrate. At least a portion of at least some of the second chip subassemblies are encapsulated to create semiconductor chip packages. The semiconductor chips may be selected with an adhesive layer on a back side thereof and the individually placing step may include placing the semiconductor chips on the individual adhesive areas with the adhesive layer contacting the adhesive at the individual adhesive areas. Various features and advantages of the invention will appear from the following description in which the preferred embodiments have been set forth in detail in conjunction with the accompanying drawings.

### BRIEF DESCRIPTION OF THE DRAWINGS

FIG. 1 is a flowchart of a conventional semiconductor packaging process in which a paste is used as the semiconductor chip-bonding adhesive;

FIG. 2 is a simplified view illustrating the wafer mounting tape lamination step of FIG. 1;

FIG. 3 is a simplified illustration of the result of the wafer dicing step of FIG. 1;

FIG. 4 illustrates a conventional diced semiconductor chip, or die, made according to the method of FIG. 1;

FIG. 5 is a flowchart of a semiconductor packaging process according to the invention;

FIG. 6 illustrates a substrate, supported by a heater block, on which adhesive has been printed at spaced apart adhesive areas;

FIG. 7 illustrates a die bonding tool mounting die to the B-staged printed adhesive at the adhesive areas to create first chip subassemblies;

FIG. 8 is an enlarged simplified side view showing the die bonding tool of FIG. 7 mounting die to the B-staged printed adhesive at the adhesive areas;

FIG. 9 shows result of connecting wires between the die and substrate of a first chip subassembly of FIG. 7 to create a second chip subassembly;

FIG. 10 illustrates an alternative embodiment to the second chip subassembly of FIG. 9 in which a second die has been mounted to the first die and wires have been mounted between the first and second die and the substrate to create a multiple chip subassembly;

FIGS. 11 shows an alternative to the structure shown in FIGS. 7 and 8 in which the die has a wafer backside laminated film adhesive secured thereto to provide enhanced adhesion between the die and the substrate;

FIG. 12 shows result of connecting wires between the die and substrate of the structure of FIG. 11 to create an alternative embodiment to the second chip subassembly of FIG. 9;

FIG. 13 shows a multiple chip subassembly similar to that of FIG. 10 but in which each die has been mounted using a wafer backside laminated film adhesive as shown in FIG. 11;

and

FIG. 14 illustrates a semiconductor chip package in which the second chip subassembly is encapsulated using a molding compound.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs.

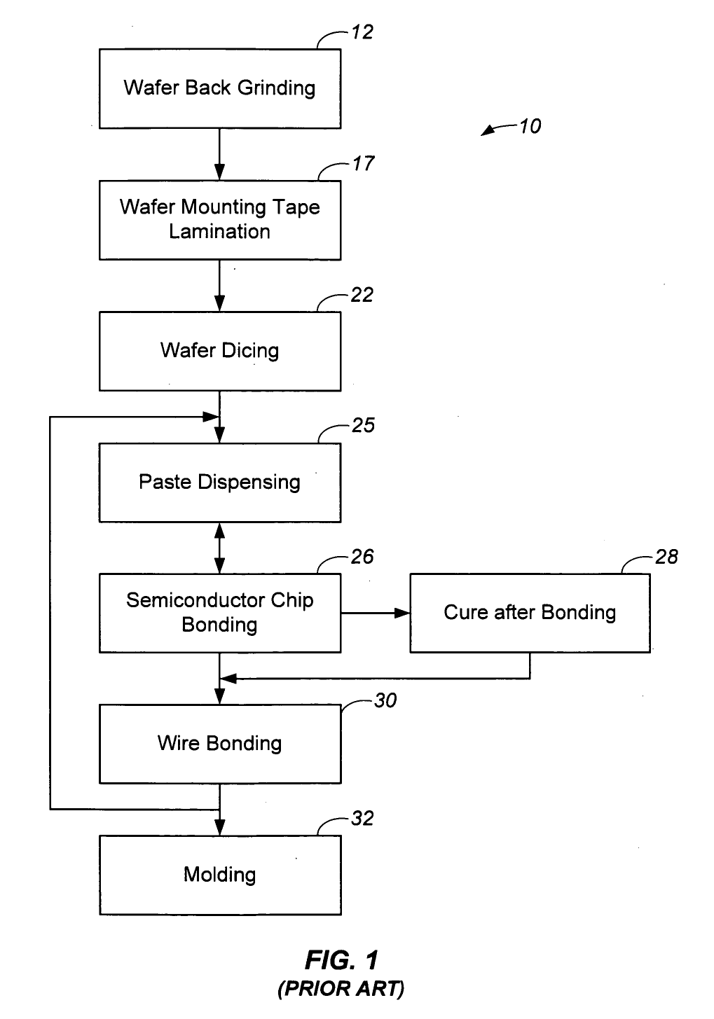

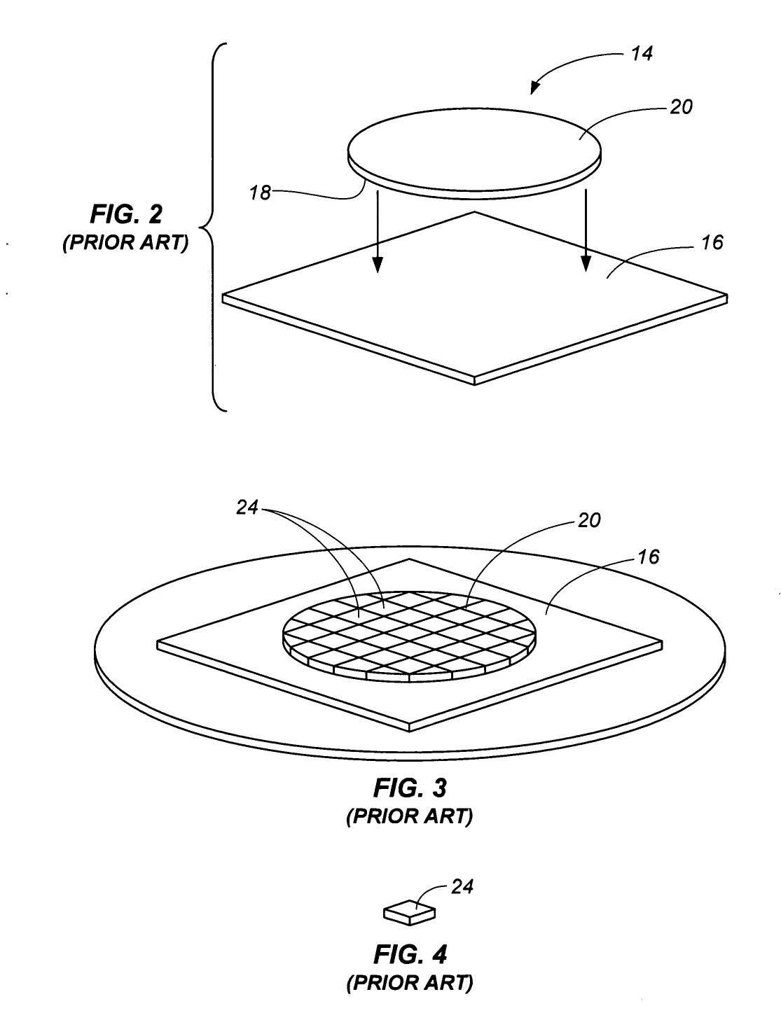

FIGS. 1-4 illustrate a conventional semiconductor packaging process 10 in which a wafer, not shown, is subjected to a wafer back grinding step 12 during which material is removed from the back or non-circuit side of the wafer. The ground wafer 14, see FIG. 2, is then laminated to a wafer mounting tape 16 during a wafer mounting tape lamination step 17 with the second, back ground side 18 (also called backside 18) being adhered to the wafer mounting tape so that the first, circuit side 20 of ground wafer 14 is exposed. The wafer-dicing step 22 is carried out to create diced semiconductor chips 24, also called die 24. Die 24 are bonded to a substrate using a paste adhesive pursuant to the paste dispensing step 25, semiconductor chip bonding step 26 and cure after bonding step 28 of FIG. 1. Thereafter the wire-bonding step 30 is carried out. Steps 25-30 may be repeated according to the number of layers of chips for the completed device. After the molding step 32, which is typically carried out using an epoxy molding compound, appropriate sawing or other severing equipment is used to cut through the substrate and, when the entire substrate is covered with molding compound, the molding compound to create the individual semiconductor chip packages. It should be noted that a residue of wafer mounting tape 16 can adhere to backside 18 of die 24 after the die has been removed from the wafer mounting tape; however, such remaining adhesive is not sufficient to create an effective bond between die 24 and the substrate so that the paste adhesive is needed.

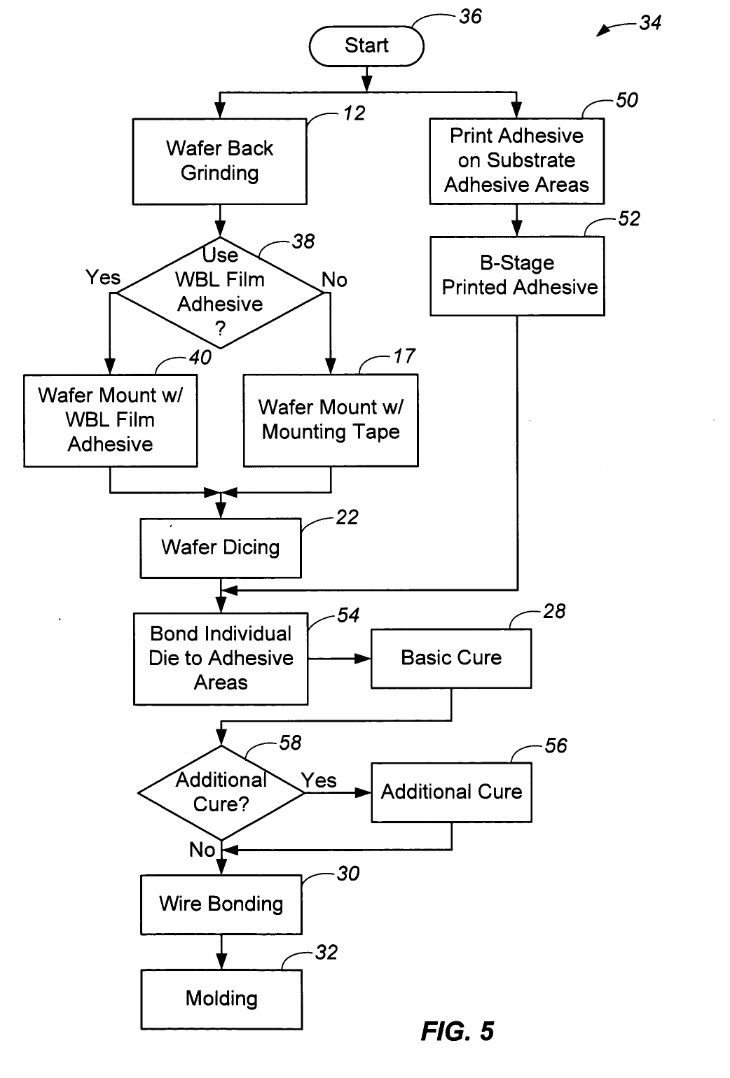

FIG. 5 is a flowchart of a semiconductor packaging process 34 according to the present invention. Portions of process 34 are similar to process 10 of FIG. 1 with like steps and elements referred to with like reference numerals.

As indicated in FIG. 5, back grinding step 12 follows start 36. At decision point 38, the decision to use wafer backside lamination film adhesive is made. Depending on the answer, ground wafer 14 is, in this embodiment, either mounted for wafer dicing with mounting tape, as in step 17, or with wafer backside lamination film adhesive, is in step 40. One conventional wafer backside lamination film adhesive is a dielectric film adhesive available from Lintec Corporation as Lintec LE5000. An advantage of using a wafer backside lamination film adhesive instead of mounting tape will be discussed below.

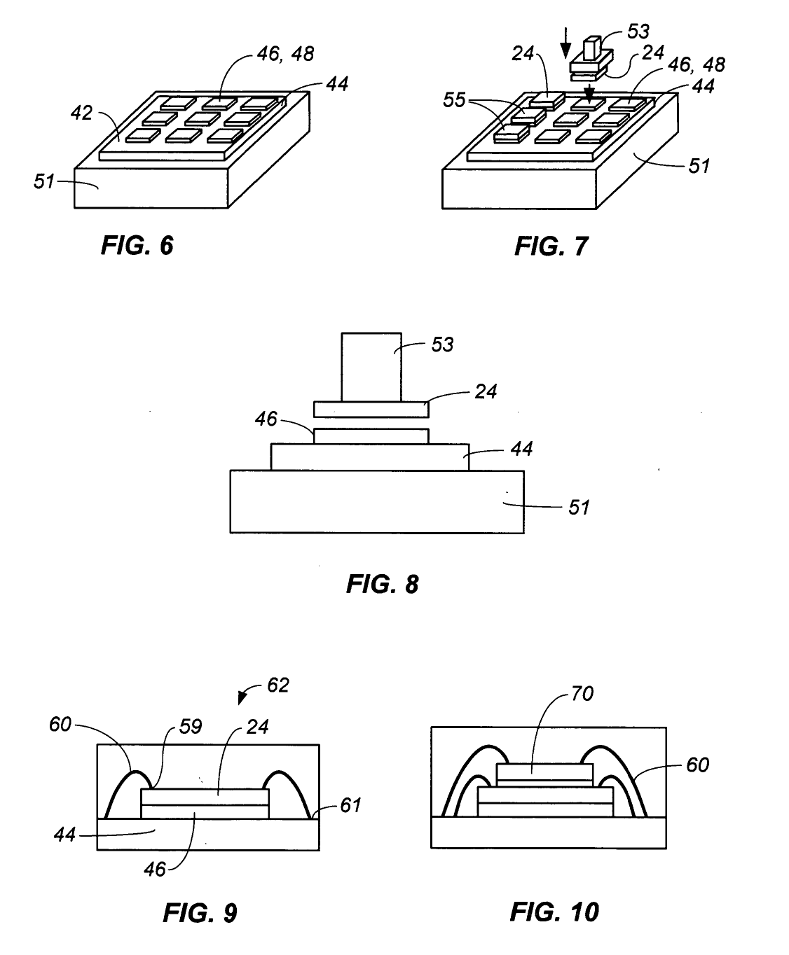

One of the main aspects of the invention is that the support surface 42, see FIG. 6, typically a surface of a substrate 44, has an adhesive 46 printed on the support surface at individual, spaced apart adhesive areas 48 as indicated in step 50 of FIG. 5. It is preferred that the printable adhesive 46 be a B-stageable adhesive. The main advantages of using B-stageable adhesives lie in their good bold line thickness and tilt control, resin bleedout/flow control, lower cost and long working life after B-staging without the disadvantages associated with film adhesive, such as higher costs and lower throughput, or the disadvantages associated with paste type adhesives, such as poor dimension control (bond line thickness), resin bleed out and flow out problems. An example of a suitable B-stageable adhesive is manufactured by Ablestik Laboratories of Rancho Dominguez, California as Able 6200. Adhesive printing step 50 is carried out using, for example, a stencil printer such that the dimensions of adhesive 46 at adhesive areas 48 are substantially the same as or smaller than the size of die 24 to be attached on adhesive 46. Other types of adhesive printing techniques, such as spraying, spin coating or syringe dispensing, can be used.

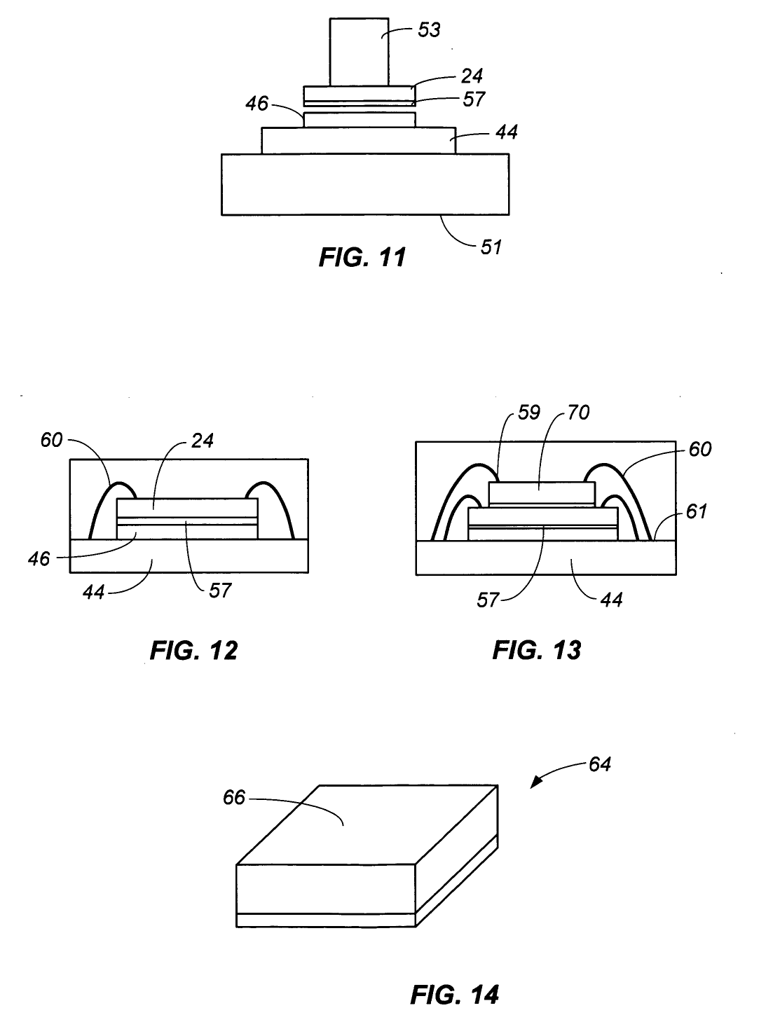

Printed adhesive 46 is B-staged at step 52, typically at an elevated temperature so that all the solvents, which control the rheology of the typically paste-type adhesive, are driven off. After B-staging, an essentially solid form of adhesive 46 remains. Die 24 are then bonded to adhesive areas 48 on substrate 44 in the die bonding step 54 of FIG. 5 using a die bonding tool 53 of FIGS. 7 and 8. Substrate 44 is supported on a heater block 51. This creates first chip subassemblies 55 (see FIG. 7). The cure after bonding step 28, which typically occurs at elevated pressure and temperature, then follows to promote complete adhesive cure and better bonding of die 24 to B-staged adhesive 46 and B-staged adhesive 46 to substrate 44. When the wafer mounting tape lamination step 17 is used, see FIG. 8, an additional cure step 56 may be required or desirable. Additional cure step 56, which typically involves an after press and/or autoclave, uses higher die attach pressures to promote better adhesion of die 24 to B-staged adhesive 46. However, when step 40, using wafer backside lamination film adhesive 57, is followed, the adhesion between die 24 and B-staged adhesive 46 is promoted by polymer-to-polymer bonding. See FIGS. 11 and 12. In this case, additional cure decision point 58 may be answered in the negative so that additional cure step 56 may be skipped.

FIGS. 9 and 12 illustrate wires 60 connecting bonding pads 59 on a single semiconductor chip 24 to bonding pads 61 on substrate 46 after wire bonding step 30 to create second semiconductor chip subassemblies 62. An individual semiconductor chip package 64 is shown in FIG. 14 after molding step 32 using an appropriate molding compound 66 and an appropriate sawing or other severing step.

The invention may also be carried out with multichip packages. These multichip packages may include a combination of circuit-containing die and spacer die. The second or subsequent die 70, see FIGS. 10 and 13, may be adhered using conventional adhesion techniques, such as paste type adhesives, wafer backside laminated adhesives or cut and placed film adhesives. However, the second or subsequent die 70 may also have a B-stageable adhesive printed onto, for example, the back side of a thinned wafer, after which the B-stageable adhesive is B-staged; thereafter the wafer and B-staged adhesive is appropriately mounted and diced to create individual die 70. Die 70 to die 24 attachment can be done using conventional die attach equipment, such as available from Esec of Cham, Switzerland as Esec 2008 at an appropriately elevated pressure and temperature. Alternatively, or in addition, the wafer from which the first (or a subsequently placed) die 24 are created could have a B-stageable adhesive printed on the top or circuit side (being careful not to cover wire bonding pads 59, 61) prior to dicing.

Other modification and variation can be made to the disclosed embodiments without departing from the subject of the invention as defined in following claims.

Any and all patents, patent applications and printed publications referred to above are incorporated by reference.

Other embodiments are within the scope of the invention.

1. A semiconductor chip packaging method comprising:
printing adhesive on a support surface to create individual adhesive areas;
individually placing semiconductor chips on the individual adhesive areas thereby securing the semiconductor chips to the support surface to create first chip subassemblies, the first chip subassemblies comprising semiconductor substrates;
electrically connecting the semiconductor chip and semiconductor substrate of each of a plurality of the first chip subassemblies to create second chip subassemblies; and
encapsulating at least a portion of at least some of the second chip subassemblies to create semiconductor chip packages.

2. The method according to claim 1 further comprising B-staging the adhesive at the individual adhesive areas before the individually placing step.

3. The method according to claim 1 wherein the B-staging the adhesive step comprises removing solvent from the adhesive.

4. The method according to claim 1 wherein the support surface is a surface of the substrate.

5. The method according to claim 1 wherein the support surface is a surface of a circuit-containing die supported by the substrate.

6. The method according to claim 1 wherein the support surface is a surface of a spacer die supported by the substrate.

7. The method according to claim 1 further comprising:
adhering a wafer mounting tape to a second side of a semiconductor wafer, the semiconductor wafer further comprising a first, circuit side; and
dicing the wafer to create the semiconductor chips.

8. The method according to claim 7 further comprising back grinding the second side prior to the adhering step.

9. The method according to claim 1 wherein the adhesive printing step comprises printing the adhesive at spaced-apart locations on the support surface.

10. The method according to claim 1:
further comprising selecting semiconductor chips having an adhesive layer on a back side thereof; and
wherein the individually placing step comprises placing the semiconductor chips on the individual adhesive areas with the adhesive layer contacting the adhesive at the individual adhesive areas.

11. The method according to claim 1 further comprising curing the adhesive following the semiconductor chip placing step.

12. The method according to claim 11 wherein the curing step comprises the application of heat.

13. The method according to claim 11 wherein the curing step comprises the application of pressure.

14. The method according to claim 11 wherein the curing step comprises the application of heat and pressure.

15. The method according to claim 1 wherein the electrically connecting step is carried out using wires.

16. The method according to claim 1 further comprising separating the semiconductor chip packages from one another.

17. The method according to claim 16 wherein the encapsulating step is carried out using a molding compound and the separating step is carried out by sawing through the support surface and the molding compound.

18. The method according to claim 1 wherein the electrically connecting step is carried out using wires between wire bond positions on the semiconductor chip and the semiconductor substrate.

19. A semiconductor chip package made according to the method of claim 1.

20. A semiconductor chip packaging method comprising:
printing adhesive on a semiconductor substrate to create individual adhesive areas; B-staging the adhesive at the individual adhesive areas, thereby removing solvent from the adhesive, before the individually placing step;
individually placing semiconductor chips on the B-staged individual adhesive areas thereby securing the semiconductor chips to the support surface to create first chip subassemblies;
electrically connecting the semiconductor chip and support surface of each of a plurality of the first chip subassemblies to create second chip subassemblies; the electrically connecting step being carried out using wires between wire bond positions on the semiconductor chip and the semiconductor substrate; and
encapsulating at least a portion of at least some of the second chip subassemblies to create semiconductor chip packages.

21. The method according to claim 20:
further comprising selecting semiconductor chips having an adhesive layer on a back side thereof; and wherein
the individually placing step comprises placing the semiconductor chips on the individual adhesive areas with the adhesive layer contacting the adhesive at the individual adhesive areas.

22. A semiconductor chip package made according to the method of claim 21.
